(19) United States
(12) Patent Application Publication
(10) Pub. No.: US 2024/0004445 A1
(43) Pub. Date: Jan. 4, 2024

(54) SYSTEM AND METHOD OF AUTOMATIC RACK WISE POWER MEASUREMENT IN A DATA CENTRE

(71) Applicant: JIO PLATFORMS LIMITED, Ahmedabad (IN)

(72) Inventors: Deepak GUPTA, Maharashtra (IN); Narender KUMAR, Haryana (IN); Nekiram KHOSYA, Maharashtra (IN); Renuka NAIR, Maharashtra (IN); Santosh Herald PINTO, Maharashtra (IN); Deepak JAGDALE, Maharashtra (IN)

(21) Appl. No.: 18/246,399

(22) PCT Filed: Jul. 27, 2022
(86) PCT No.: PCT/IB2022/056923

§ 371 Date: Mar. 23, 2023

(30) Foreign Application Priority Data
Jul. 28, 2021 (IN) 202121033849

(51) Int. Cl. G06F 1/26

(52) U.S. Cl. CPC G06F 1/26

(57) ABSTRACT

The present invention provides a robust and effective solution to an entity or an organization by enabling them to implement a system (110) and method (300) for facilitating monitoring of power usage at each rack level in a data centre (108) through a plurality of loT based wireless sensor devices. (116) By measuring power at each rack level and collating those for a data centre infrastructure will give a true picture of data centre power efficiency.

### FIELD OF INVENTION

The embodiments of the present disclosure generally relate to data monitoring data centre assets. More particularly, the present disclosure relates to design a sensor network to monitor power in each rack of a data centre.

### BACKGROUND OF THE INVENTION

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Along with the growth of digital services and devices, the typical cloud data centre environment has grown. The storage systems today are often organized in data centres. Such data centres may contain hundreds or thousands of computers. There is a large collection of interconnected servers that provide computing and/or storage capacity to run various applications. A data centre may comprise a facility that hosts applications and services for subscribers, i.e., customers or users of data centre. The data centre may, for example, host all the infrastructure equipment, such as networking and storage systems, redundant power supplies, and environmental controls. In a typical data centre, clusters of storage systems and application servers are interconnected via high-speed switch fabric provided by one or more tiers of physical network switches and routers. More sophisticated data centres provide infrastructure spread throughout the globe with subscriber support equipment located in various physical hosting facilities. Many data centres today are dependent on the physical infrastructure of a particular data centre. A data centre can be modelled as rows of racks that house electronic systems, such as computing systems or other types of electrical devices. The computing systems (such as computers, storage devices, servers, routers, networking devices, etc.) consume power for their operation. The computing systems of the data centre may reside in these racks. In a typical data centre, there may be dozens or even hundreds of electrical devices. Each of these devices is connected to an electrical power source.

Hence, along with the growth of digital services and devices, the typical cloud data centre environment has grown. The storage systems today are often organized in data centres. Such data centres may contain hundreds or thousands of computers. There is a large collection of interconnected servers that provide computing and/or storage capacity to run various applications. A data centre may comprise a facility that hosts applications and services for subscribers, i.e., customers or users of data centre. The data centre may, for example, host all the infrastructure equipment, such as networking and storage systems, redundant power supplies, and environmental controls. In a typical data centre, clusters of storage systems and application servers are interconnected via high-speed switch fabric provided by one or more tiers of physical network switches and routers. More sophisticated data centres provide infrastructure spread throughout the globe with subscriber support equipment located in various physical hosting facilities. Many data centres today are dependent on the physical infrastructure of a particular data centre. A data centre can be modelled as rows of racks that house electronic systems, such as computing systems or other types of electrical devices. The computing systems (such as computers, storage devices, servers, routers, networking devices, etc.) consume power for their operation. The computing systems of the data centre may reside in these racks. In a typical data centre, there may be dozens or even hundreds of electrical devices. Each of these devices is connected to an electrical power source.

To expand further, a data centre is a physical facility that organizations or entities use to house their critical applications and data. The key components of a data centre design include routers, switches, firewalls, storage systems, servers, and application-delivery controllers. Typically, in a data centre hundreds of racks are installed, power with megawatt capacity are provisioned and huge capacity of cooling infrastructure is provided. A huge amount of CAPEX is invested initially to build a data centre. While spending this huge CAPEX, it is worthy to use these resources at its maximum efficiency during its operations. And to know the usage of resources in data centre operations smart monitoring devices are required. To manage power in most efficient manner it is necessary to monitor few critical parameters at a micro level—in each rack inside the data centre. Existing systems have many issues that create a chain of undesirable side effects such as equipment lying in the warehouse awaiting installation, uneconomical use of space creating a perception of scarcity, need for personal intervention to get ‘reserved’ space vacated and general lack of transparency. The issues are as follows:
Poor visibility on power utilization
Manual and incomplete data collection
No real time monitoring tools in Jio facilities
Management through Excel Work sheets

In recent years, as data centres have grown in size and complexity, the tools that manage them must be able to effectively identify power consumption while implementing appropriate policies. Traditionally, network administrators have to manually implement policies, manage access control lists (MACLs), configure lists, de-power misconfigured or infected machines, diagnose the infected resources, etc. These tasks can become exponentially more complicated as a network grows in size and require an intimate knowledge of power consumption of a large number of data centre components. Furthermore, misconfigured machines can shut down a data centre within minutes while it could take a network administrator hours or days to map and determine the root problem and provide a power solution.

The existing data centres do not have the facility to measure power rack wise in a data centre. There has been a repetitive and a time-consuming exercise whenever any new product or service is to be deployed as part of core infrastructure in the data centres and other facilities. An efficient and transparent management system also has to be created for the racks and power in all facilities. As the network expands and new sites are added, the efficient use of power become even more critical. As of now, there is no tool available by which power availability and consumption can be checked in real time. At present everything is managed through excel worksheets and may not reflect the recent status. There may be sensors for large facilities to measure power but these generally contribute to unnecessary delays in project execution running into months and even quarters and are very expensive. Separate sensors exist for current measurement, voltage measurement, humidity and temperature measurement which is not only costly but also very complex to maintain as each sensor requires a separate wiring mechanism to a gateway terminal. There is, therefore, a need in the art to provide a system and a method that facilitates measuring of power rack wise in a data centre by mitigating the limitations in the art.

There is need for a system that aims to monitor power usage at each rack level in a data centre through IoT based wireless sensor devices and collating those for a data centre infrastructure in order to give a true picture of data centre power consumption efficiency.

### OBJECTS OF THE PRESENT DISCLOSURE

Some of the objects of the present disclosure, which at least one embodiment herein satisfies are as listed herein below.

It is an object of the present disclosure to provide a system and a method to facilitate measurement of rack wise power in a data centre for large facilities.

It is an object of the present disclosure to provide a system to mitigate the current four key pain-points which contribute to unnecessary delays in project execution running into months and even quarters.

It is an object of the present disclosure to provide a system and a method to monitor power usage at each rack/component level in a data centre.

It is an object of the present disclosure to provide a system and a method for collating power measurements for a data centre infrastructure to give a true picture of the power efficiency.

It is an object of the present disclosure to provide a system that eliminates a huge number of cables and wires to identify power consumption.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure provides for a system for facilitating rack wise power measurement of a data centre of an entity. The system may include a wireless sensor monitoring device operatively coupled to a processor through a network. In an embodiment, the wireless sensor monitoring device may include a plurality of sensors operatively coupled to a plurality of racks of the data centre. The plurality of sensors may be configured to sense a current flowing through each rack of the data centre and may output a voltage corresponding to the current. The processor may be operatively coupled to the plurality of sensors through a network. The processor may be coupled with a memory that may store instructions which when executed by the processor may cause the processor to receive a first set of signals from the plurality of sensors, the first set of signals pertaining to a DC current and voltage corresponding to each of the plurality of racks. The processor may receive a second set of signals from the plurality of sensors, the second set of signals pertaining to an AC current and voltage flow corresponding to each of the plurality of racks. The processor may then extract a first set of attributes from the first set of signals, the first set of attributes pertaining to one or more sampled values of the DC current and voltage and then further extract a second set of attributes from the second set of signals, the second set of attributes pertaining to one or more sampled values of the AC current and voltage. Based on the extracted first and second set of attributes, calculate a power value for each first and second set of attributes associated with each rack extracted within a specified interval of time.

In an embodiment, the processor may further determine a cumulative energy from the power value for each first and second set of attributes extracted over the specified interval of time and then further determine a total power required by the plurality of racks of the data centre.

In an embodiment, the plurality of sensors may be operatively coupled to a wireless sensor monitoring network that may further include a wireless gateway device.

In an embodiment, the plurality of sensors may be any or a combination of one or more DC Smart Power Sensors and one or more AC Smart Power Sensors.

In an embodiment, the wireless gateway device may be configured to manage the plurality of sensors.

In an embodiment, the plurality of sensors and the wireless monitoring device may be installed such that the plurality of sensors and the wireless monitoring device may not require any rack space and have zero service downtime.

In an embodiment, the plurality of sensors and the wireless monitoring device may be integrated with an antenna of the network (106) without disturbing the property of the antenna.

In an embodiment, the wireless gateway device may be configured to support a predefined number of wireless devices.

In an embodiment, a centralised server operatively coupled to the processor may include a database and the database may store a plurality of DC current and voltages, a plurality of AC currents and voltages, a plurality of sampled AC and DC current and voltage values, a plurality of power values corresponding to the sampled AC and DC current and voltage values of the plurality of racks of the data centre.

In an embodiment, a user device may be communicably coupled to the centralized server through the network that may enable a user to store, access and monitor the power being consumed by each rack of the data centre remotely through the network.

In an aspect, the present disclosure provides for a method for facilitating rack space measurement of a data centre of an entity. The method may include the step of receiving, by a processor, a first set of signals from the plurality of sensors, the first set of signals pertaining to a DC current and voltage flowing through each rack of a data centre. In an embodiment, the plurality of sensors may be operatively coupled to a plurality of racks of the data centre. The plurality of sensors may be configured to sense a current flowing through each rack of the data centre and may output a voltage corresponding to the current. The processor may be wirelessly coupled to the plurality of sensors through a network. The processor may be coupled with a memory that may store instructions to be executed by the processor. The method may include the step of receiving, by the processor, a second set of signals from the plurality of sensors, the second set of signals pertaining to an AC current and voltage flowing through each rack. Further, the method may include the steps of extracting, by the processor, a first set of attributes from the first set of signals, the first set of attributes pertaining to one or more sampled values of the DC current and voltage and extracting, by the processor, a second set of attributes from the second set of signals, the second set of attributes pertaining to one or more sampled values of the AC current and voltage. Based on the extracted first and second set of attributes, the method then may include the step of calculating, by the processor, a power value for each first and second set of attributes extracted within a specified interval of time.

Thus, the above embodiments can easily meet the objectives such as facilitating measurement of rack wise power in the data centre for large facilities, mitigating to unnecessary delays in project execution running into months and even quarters, monitoring power usage at each rack/component level in a data centre., collating power measurements for a data centre infrastructure to give a true picture of the power efficiency and the use of a wireless network eliminates a huge number of cables and wires to identify power consumption.

### BRIEF DESCRIPTION OF DRAWINGS

The accompanying drawings, which are incorporated herein, and constitute a part of this invention, illustrate exemplary embodiments of the disclosed methods and systems in which like reference numerals refer to the same parts throughout the different drawings. Components in the drawings are not necessarily to scale, emphasis instead being placed upon clearly illustrating the principles of the present invention. Some drawings may indicate the components using block diagrams and may not represent the internal circuitry of each component. It will be appreciated by those skilled in the art that invention of such drawings includes the invention of electrical components, electronic components or circuitry commonly used to implement such components.

FIG. 1A illustrates an exemplary network architecture in which or with which the system (110) of the present disclosure can be implemented, in accordance with an embodiment of the present disclosure.

FIG. 1B illustrates an exemplary network architecture of a wireless network gateway device (120) of the present disclosure can be implemented, in accordance with an embodiment of the present disclosure.

FIG. 2A illustrates an exemplary representation (200) of the system (110), in accordance with an embodiment of the present disclosure.

FIG. 2B illustrates an exemplary representation (250) of the wireless network gateway device (120), in accordance with an embodiment of the present disclosure.

FIG. 3 illustrates exemplary method flow diagram (300) depicting a method for facilitating rack wise power measurement, in accordance with an embodiment of the present disclosure.

FIG. 4 illustrates an exemplary representation (400) of a Functional Block Diagram of DC Smart Power Sensor and its implementation, in accordance with an embodiment of the present disclosure.

FIG. 5A illustrates an exemplary representation (500) of a flow diagram for DC Power Measurement method, in accordance with an embodiment of the present disclosure.

FIG. 5B illustrates an exemplary representation (500) of a DC Power sensor, in accordance with an embodiment of the present disclosure.

FIG. 6 illustrates an exemplary representation (600) of a Functional Block Diagram of AC Smart Power Sensor and its implementation, in accordance with an embodiment of the present disclosure.

FIG. 7A illustrates an exemplary representation (700) of a flow diagram for AC Power Measurement method, in accordance with an embodiment of the present disclosure.

FIG. 7B illustrates an exemplary representation (700) of an AC Power sensor, in accordance with an embodiment of the present disclosure.

FIG. 7C illustrates a front view and an iso metric view representation of the DC Power sensor, the AC power sensor and other sensors in a rack of a data centre, in accordance with an embodiment of the present disclosure.

FIGS. 8A-8B illustrate exemplary representations of a Functional Block diagram of Wireless Network Gateway and its implementation, in accordance with an embodiment of the present disclosure.

FIG. 9 illustrates an exemplary representation (900) of a flow diagram of data flow from the rack sensor to cloud, in accordance with an embodiment of the present disclosure.

FIG. 10 illustrates an exemplary computer system in which or with which embodiments of the present invention can be utilized in accordance with embodiments of the present disclosure.

The foregoing shall be more apparent from the following more detailed description of the Invention.

### BRIEF DESCRIPTION OF INVENTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The present invention provides a robust and effective solution to an entity or an organization by enabling them to implement a system for monitoring of power usage at each rack level in a data centre through IoT based wireless sensor devices. By measuring power at each rack level and collating those for a data centre at an infrastructure wide level will give a true picture of data centre efficiency.

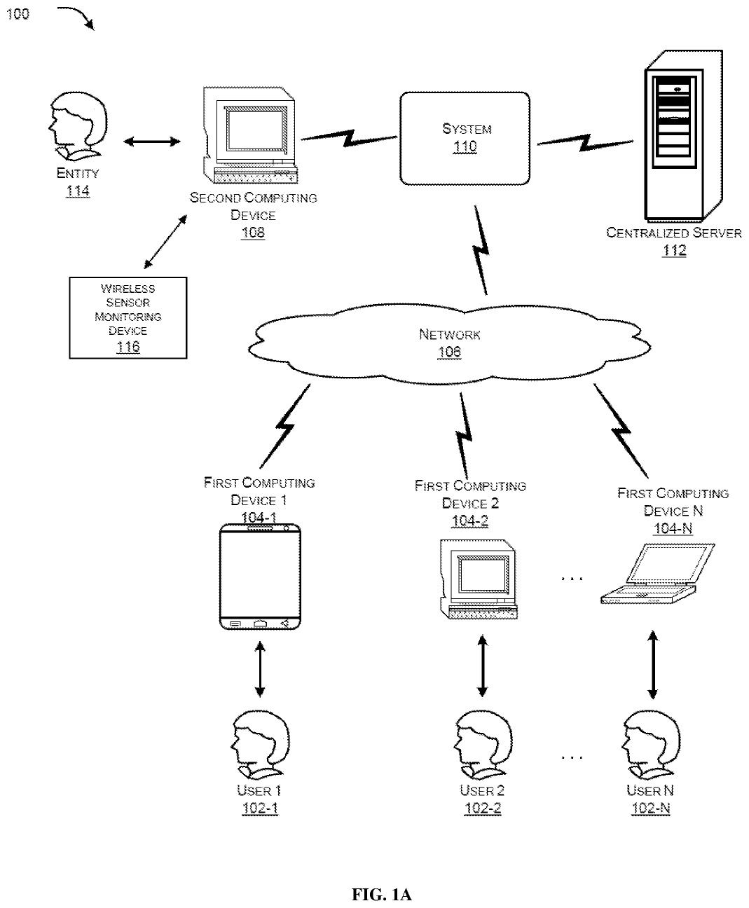

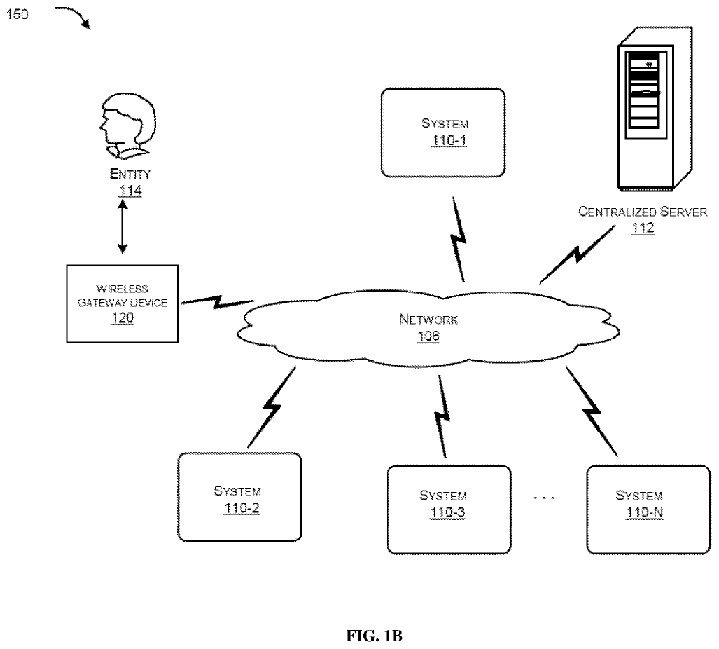

Referring to FIG. 1A that illustrates an exemplary network architecture (100) in which or with which system (110) of the present disclosure can be implemented, in accordance with an embodiment of the present disclosure. As illustrated in FIG. 1, by way of example but not limitation, the exemplary architecture (100) may include a user (102) associated with a user computing device (104) (also referred to as user device (104)), at least a network (106) and at least a centralized server (112). More specifically, the exemplary architecture (100) includes a system (110) for facilitating rack wise power measurement of a second computing device (108) (also referred to as the data centre (108) hereinafter) of an entity (114). The entity (114) may include a company, an organisation, a university, a lab facility, a business enterprise, a defence facility, or any other secured facility. The data centre (108) may include a plurality of racks and each rack may further include a plurality of levels wherein a predefined amount of data may be stored. The system (110) may further include a wireless network monitoring device (116). The wireless network monitoring device (116) may include a plurality of sensors (not shown in the FIG. 1A) operatively coupled to a plurality of racks of the data centre (108).

A plurality of computing devices may reside in each rack of the plurality of racks in the data centre (108). For example, the plurality of computing devices may include computers, storage devices, servers, routers, networking devices, and the like. The system (110) may further include a processor that may be wirelessly coupled to the plurality of sensors through the network (106). The processor may cause the system (110) to: receive a first set of signals from the plurality of sensors corresponding to a DC current and voltage and receive a second set of signals from the plurality of wireless sensors corresponding to an AC current and voltage. Furthermore, the processor may cause the system to extract a first set of attributes from the first set of signals, the first set of attributes corresponding to sampled values of the DC current and voltage and also extract a second set of attributes from the second set of signals, the second set of attributes corresponding to sampled values of the AC current and voltage. Based on the extracted first and second set of attributes, the processor may calculate a power value for each first and second set of attributes extracted within a specified interval of time and then determine a cumulative energy from the power value for each first and second set of attributes extracted over the specified interval of time. From the cumulative energy, a total power required by the plurality of racks in the data centre can be clearly determined.

In an embodiment, the processor (202) may further cause the system (110) to determine a cumulative energy from the power value for each first and second set of attributes extracted over the specified interval of time. The system (110) also can determine a total power consumed by the plurality of racks in the data centre (1080.

In an embodiment, the wireless sensor monitoring device further may include a processing unit such as but not limited to a microcontroller unit (MCU). The wireless sensor monitoring device may further include an antenna operatively coupled to a transceiver and one more module coupled to a DC circuitry. In an embodiment, the plurality of sensors may be any or a combination of one or more DC Smart Power Sensors and one or more AC Smart Power Sensors. The plurality of sensors may be of a predefined size placed at predetermined locations in each rack. For example, the one or more DC sensors may have a size of but not limited to 84 mm×63 mm×31 mm and weigh around 100 gm. The one or more AC sensors may have a size of but not limited to 84 mm×63 mm×31 mm and weigh around 100 gm.

In an embodiment, the centralised server (112) may store a plurality of DC current and voltages, a plurality of AC currents and voltages, a plurality of sampled AC and DC current and voltage values, a plurality of power values corresponding to the sampled AC and DC current and voltage values.

The user device (104) may enable the user to store/access and monitor the power being consumed by each rack of the data centre (108) remotely through the network (106).

Referring to FIG. 1B that illustrates an exemplary network architecture (100) in which or with a wireless network gateway device (120) of the present disclosure can be implemented, in accordance with an embodiment of the present disclosure. The wireless network gateway device (120) (also referred to as wireless gateway device (120) hereinafter) for collecting a rack wise power measurement data of the data centre (108) of the entity (114). The wireless gateway device (120) may include an antenna unit that may be configured to collect the rack wise power measurement data determined by the system (110). The wireless gateway device (120) may further include a local area network (LAN) operatively coupled to the centralized server (112) through the network (106) and a processor (222). The wireless gateway device (120) may be configured to receive the amount of the rack wise power measurement data determined by the system (110) and then transmit the received the rack wise power measurement data to the centralized server (112). The wireless gateway device (120) may be of a predetermined size that do not require any rack space. For example, the wireless gateway device may have a size of but not limited to 82 mm×62 mm×28 mm and a weight of about 100 gm.

In an embodiment, the data centre (108) and/or the user device (104) may communicate with the system (110) via set of executable instructions residing on any operating system, including but not limited to, Android™, iOS™, Kai OS™ and the like. In an embodiment, data centre (108) and/or the user device (104) may include, but not limited to, any electrical, electronic, electro-mechanical or an equipment or a combination of one or more of the above devices such as mobile phone, smartphone, virtual reality (VR) devices, augmented reality (AR) devices, laptop, a general-purpose computer, desktop, personal digital assistant, tablet computer, mainframe computer, or any other computing device, wherein the computing device may include one or more in-built or externally coupled accessories including, but not limited to, a visual aid device such as camera, audio aid, a microphone, a keyboard, input devices for receiving input from a user such as touch pad, touch enabled screen, electronic pen and the like. It may be appreciated that the computing device (104) and/or the user device (120) may not be restricted to the mentioned devices and various other devices may be used. A smart computing device may be one of the appropriate systems for storing data and other private/sensitive information.

In an exemplary embodiment, a network 106 may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. A network may include, by way of example but not limitation, one or more of: a wireless network, a wired network, an internet, an intranet, a public network, a private network, a packet-switched network, a circuit-switched network, an ad hoc network, an infrastructure network, a public-switched telephone network (PSTN), a cable network, a cellular network, a satellite network, a fiber optic network, some combination thereof.

In another exemplary embodiment, the centralized server (112) may include or comprise, by way of example but not limitation, one or more of: a stand-alone server, a server blade, a server rack, a bank of servers, a server farm, hardware supporting a part of a cloud service or system, a home server, hardware running a virtualized server, one or more processors executing code to function as a server, one or more machines performing server-side functionality as described herein, at least a portion of any of the above, some combination thereof.

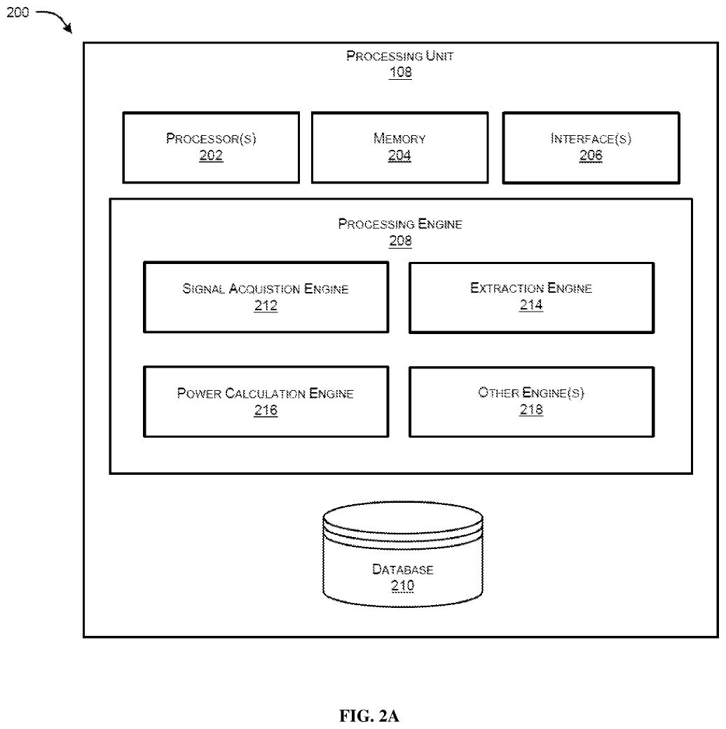

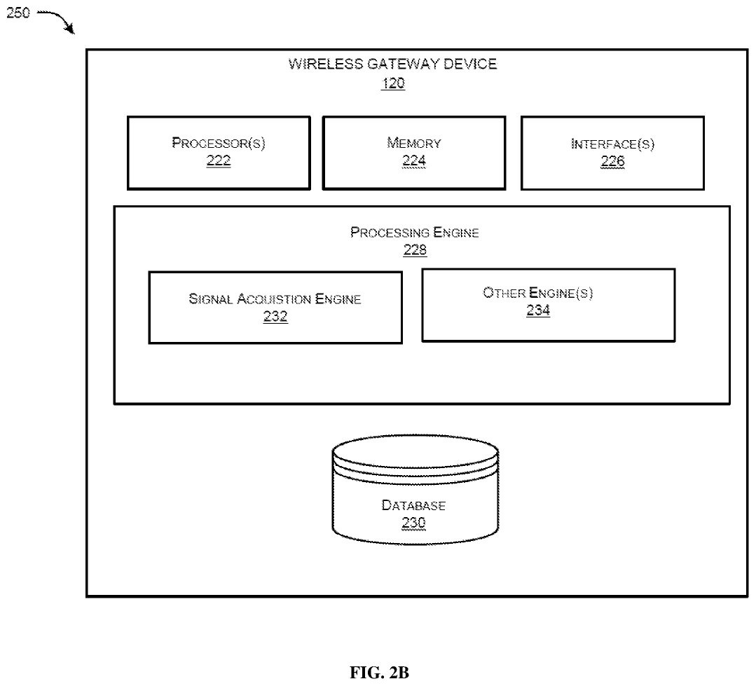

In an embodiment, the system (110) may include one or more processors coupled with a memory, wherein the memory may store instructions which when executed by the one or more processors may cause the system to automatically measure power consumed by each rack in a data centre (108). FIG. 2A with reference to FIG. 1A, illustrates an exemplary representation of system (110) for facilitating automatic power measurement, in accordance with an embodiment of the present disclosure. In an aspect, the system (110) may comprise one or more processor(s) (202). The one or more processor(s) (202) may be implemented as one or more microprocessors, microcomputers, microcontrollers, digital signal processors, central processing units, logic circuitries, and/or any devices that process data based on operational instructions. Among other capabilities, the one or more processor(s) (202) may be configured to fetch and execute computer-readable instructions stored in a memory (204) of the system (110). The memory (204) may be configured to store one or more computer-readable instructions or routines in a non-transitory computer readable storage medium, which may be fetched and executed to create or share data packets over a network service. The memory (204) may comprise any non-transitory storage device including, for example, volatile memory such as RAM, or non-volatile memory such as EPROM, flash memory, and the like.

In an embodiment, the system (110) may include one or more interface(s) 206. The interface(s) 206 may comprise a variety of interfaces, for example, interfaces for data input and output devices, referred to as I/O devices, storage devices, and the like. The interface(s) 206 may facilitate communication of the system (110). The interface(s) 206 may also provide a communication pathway for one or more components of the system (110). Examples of such components include, but are not limited to, processing engine(s) 208 and a database 210.

The processing engine(s) (208) may be implemented as a combination of hardware and programming (for example, programmable instructions) to implement one or more functionalities of the processing engine(s) (208). In examples described herein, such combinations of hardware and programming may be implemented in several different ways. For example, the programming for the processing engine(s) (208) may be processor executable instructions stored on a non-transitory machine-readable storage medium and the hardware for the processing engine(s) (208) may comprise a processing resource (for example, one or more processors), to execute such instructions. In the present examples, the machine-readable storage medium may store instructions that, when executed by the processing resource, implement the processing engine(s) (208). In such examples, the system (110) may comprise the machine-readable storage medium storing the instructions and the processing resource to execute the instructions, or the machine-readable storage medium may be separate but accessible to the system (110) and the processing resource. In other examples, the processing engine(s) (208) may be implemented by electronic circuitry.

The processing engine (208) may include one or more engines selected from any of a signal acquisition engine (212), an extraction engine (214), a power calculation engine (216), and other engines (218). In an embodiment, the signal acquisition engine (212) is configured to receive a first set of signals from a plurality of wireless sensors corresponding to a DC current and voltage and receive a second set of signals from a plurality of wireless sensors, the second set of signals may correspond to an AC current and voltage.

The extraction engine (214) may extract first set of attributes from the first set of signals, the first set of attributes corresponding to sampled values of the DC current and voltage and also extract a second set of attributes from the second set of signals, the second set of attributes corresponding to sampled values of the AC current and voltage. While the power calculation engine (216) may calculate a power value for each first and second set of attributes extracted within a specified interval of time and then determine a cumulative energy from the power value for each first and second set of attributes extracted over the specified interval of time.

In an embodiment, the wireless network device (120) may include one or more processors coupled with a memory, wherein the memory may store instructions which when executed by the one or more processors may cause the wireless network device (120) to automatically capture rack wise power measurement data in a data centre (108). FIG. 2B with reference to FIG. 1B, illustrates an exemplary representation of the wireless network device (120), in accordance with an embodiment of the present disclosure. In an aspect, the wireless network device (120) may comprise one or more processor(s) (222). The one or more processor(s) (222) may be implemented as one or more microprocessors, microcomputers, microcontrollers, digital signal processors, central processing units, logic circuitries, and/or any devices that process data based on operational instructions. Among other capabilities, the one or more processor(s) (222) may be configured to fetch and execute computer-readable instructions stored in a memory (224) of the wireless network device (120). The memory (224) may be configured to store one or more computer-readable instructions or routines in a non-transitory computer readable storage medium, which may be fetched and executed to create or share data packets over a network service. The memory (224) may comprise any non-transitory storage device including, for example, volatile memory such as RAM, or non-volatile memory such as EPROM, flash memory, and the like.

In an embodiment, the wireless network device (120) may include an interface(s) 226. The interface(s) 226 may comprise a variety of interfaces, for example, interfaces for data input and output devices, referred to as I/O devices, storage devices, and the like. The interface(s) 226 may facilitate communication of the wireless network device (120). The interface(s) 226 may also provide a communication pathway for one or more components of the wireless network device (120). Examples of such components include, but are not limited to, processing engine(s) (228) and a database (230).

The processing engine(s) (228) may be implemented as a combination of hardware and programming (for example, programmable instructions) to implement one or more functionalities of the processing engine(s) (228). In examples described herein, such combinations of hardware and programming may be implemented in several different ways. For example, the programming for the processing engine(s) (228) may be processor executable instructions stored on a non-transitory machine-readable storage medium and the hardware for the processing engine(s) (228) may comprise a processing resource (for example, one or more processors), to execute such instructions. In the present examples, the machine-readable storage medium may store instructions that, when executed by the processing resource, implement the processing engine(s) (228). In such examples, the wireless network device (120) may comprise the machine-readable storage medium storing the instructions and the processing resource to execute the instructions, or the machine-readable storage medium may be separate but accessible to the wireless network device (120) and the processing resource. In other examples, the processing engine(s) (228) may be implemented by electronic circuitry.

The processing engine (228) may include one or more engines selected from any of a signal acquisition engine (232), and other engines (234).

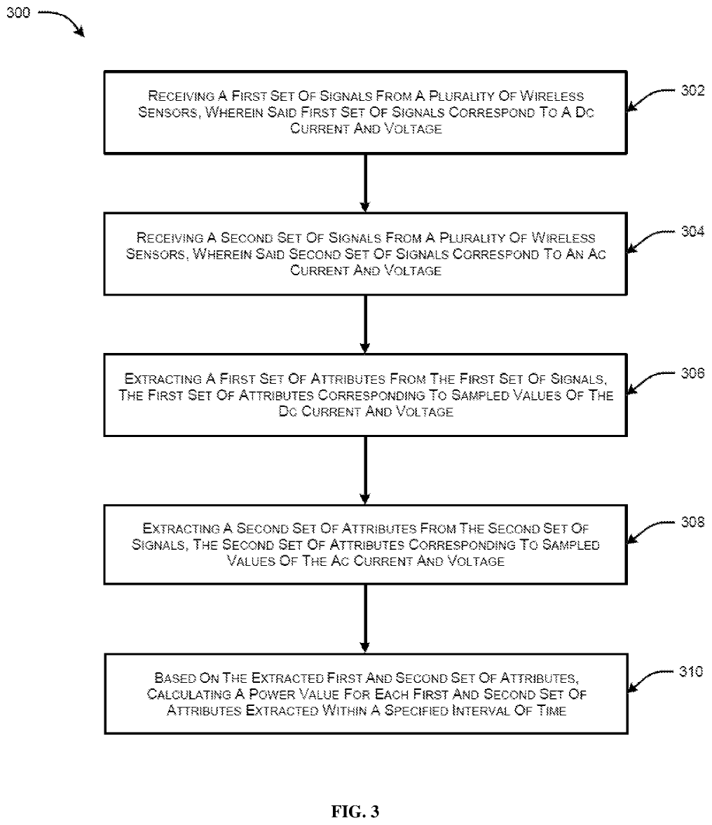

FIG. 3 illustrates exemplary method flow diagram (300) depicting a method for facilitating format-preserving encryption (FPE), in accordance with an embodiment of the present disclosure.

As illustrated, in an aspect the method may facilitate measurement of power in each rack of a data centre. The method may include at 302, the step for receiving a first set of signals from a plurality of sensors corresponding to a DC current and voltage corresponding to each of the plurality of racks. Further, the method may include at 304, the step for receiving a second set of signals from a plurality of wireless sensors, the second set of signals may correspond to an AC current and voltage corresponding to each of the plurality of racks.

Furthermore, the method may include at 306, the step for extracting a first set of attributes from the first set of signals, the first set of attributes corresponding to sampled values of the DC current and voltage; and at 308, the step for extracting a second set of attributes from the second set of signals, the second set of attributes corresponding to sampled values of the AC current and voltage. Based on the extracted first and second set of attributes, at 310 the method (300) may include the step for calculating a power value for each first and second set of attributes extracted within a specified interval of time and then at 312, the step for determining a cumulative energy from the power value for each first and second set of attributes extracted over the specified interval of time.

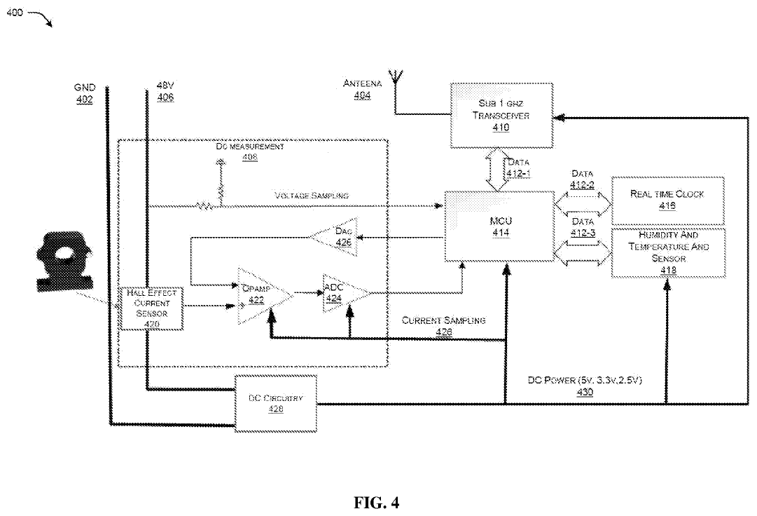

FIG. 4 illustrates an exemplary representation (400) of a functional block diagram of DC smart power sensor and its implementation, in accordance with an embodiment of the present disclosure. As illustrated in an aspect, the proposed dc smart sensor (400) continuously may measure at least −48V DC input supply current and voltage (408) and keeps accumulating the total energy consumed by a load in a device storage. All the energy consumption data may be appropriately time stamped using a Real Time Clock 416 (RTC 416) for data analytics purposes in the cloud. The accumulated energy consumption data may be pushed periodically as per network driven scheduling mechanism.

In an embodiment, a plurality of sensors (also referred to as devices hereinafter) may communicate with a wireless gateway device (also referred to as the energy measurement gateway device) in the network (106) for pushing an energy consumption data as per scheduled configuration. The Devices may have at least two separate Analog to Digital Converters (424) (ADC 424)) for measuring current and voltage information which may be further processed by a processor (414) with digital signal processing (DSP) capability to calculate DC Power Consumption but not limited to it. The data communication RF interface between the energy measurement gateway device and the devices may be based on sub-GHz connectivity.

In an exemplary embodiment, the plurality of sensors may include a Hall Effect current sensor (420) which is a current sensing device based on Hall Effect. The Hall Effect current sensor (420) may sense the current flowing through it and may output a voltage corresponding to the current. The output voltage may be given as one input to a comparator (422) that may be an operational amplifier (422) (Opamp 422) may be used to rail output operational amplifier which may be utilized as the comparator. The functional block diagram of DC smart power sensor (400) may further include a Digital to Analog converter (426) (DAC 426) which may be a 12-bit DAC but not limited to it. The DAC 426 may be utilized to give an analog input to the comparator. The ADC (424) may be at least a 14-bit ADC but not limited to it which may be used to complete the current sampling. The output of the ADC (424) may be sent to the processor (414) to get the current values. In an exemplary embodiment, the processor (414) may be a Microcontroller Unit (MCU) which is a low power high performance microcontroller having all the needed data interfaces and peripherals. It is the brain of the design and all the data processing and calculations are done by it. It is the master of the complete design and generating instructions for the other devices in the design. In an exemplary embodiment, sub-GHz connectivity may be achieved by a sub-1 GHz Transceiver (410). The sub-1 GHz Transceiver (410) may be an IEEE 802.15.4 compliant RF module for sub-1 GHz but not limited to it. The sub-1 GHz Transceiver (410) may be utilized to transfer the first set of signals at RF frequency. The sub-1 GHz Transceiver (410) may interact with the MCU (414) and upon instructions by the MCU (414) may transfer the first set of signals to an antenna (404). The antenna (404) may be sub-1 GHz matched and may be used to achieve efficient wireless communication with the energy measurement gateway device. A DC circuitry (428) comprising a plurality of DC-DC convertors may be used to generate the required voltage supplies 5V, 3.3V and 2.5V for the DC smart power sensor board. The plurality of sensors may further include a temperature and humidity sensor (418) that may be a sensor chipset which may check temperature and humidity, and may update the MCU (414) of the measurements in a periodic manner which is controllable at the MCU (414).

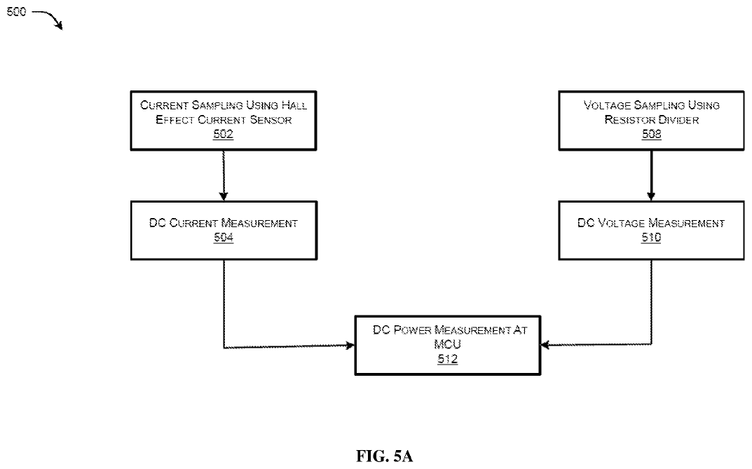

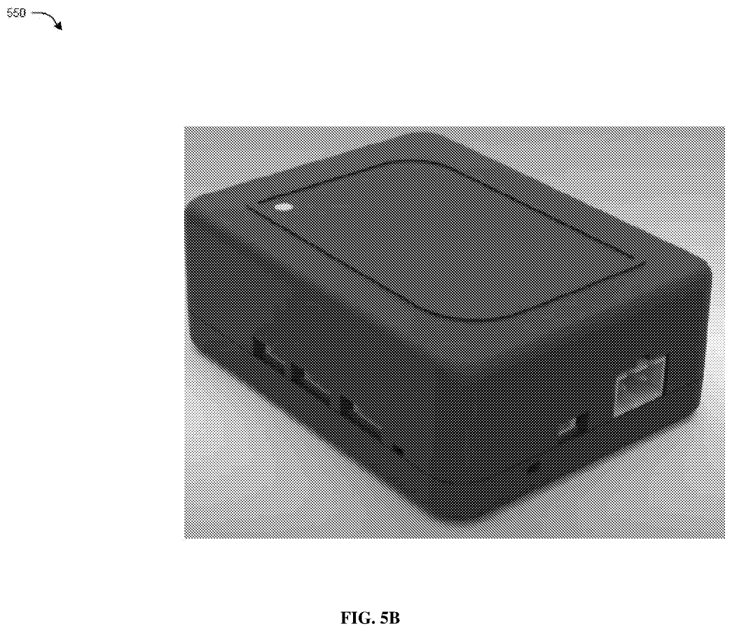

FIG. 5A illustrates an exemplary representation (500) of a flow diagram for DC Power Measurement method, in accordance with an embodiment of the present disclosure.

As illustrated, the DC Power measurement operation can be sub-divided into at least two operations of a DC current measurement and a DC voltage measurement. Steps followed in the DC power measurement may include at 508 a DC voltage sampling using a resistor divider circuit and the voltage may be read at the ADC (424). The DC power measurement may also include at 502 a step of DC current sampling using the Hall effect current sensor (420) which may sense the current and output the current as a voltage which may be read using the ADC (424). The ADC (424) measurements comprising the current measurement at 504 and the voltage measurement at 510 may be further converted into their corresponding current and voltage at the MCU after considering the electronic circuit characteristic parameters. The current and voltage sampling may be done every 5 seconds but not limited to it to take instantaneous measurements. At 512, the DC power measurement may include the step of calculating power calculations using the voltage and current values measured in the above step. The power samples may be accumulated to calculate the cumulative energy over a specified time interval.

FIG. 5B illustrates an exemplary representation (550) of a DC Power sensor, in accordance with an embodiment of the present disclosure. In a way of example and not as a limitation, Table 1 highlights exemplary features of the DC power sensor.

| | |
|---|---|
| Network interface | Wireless |
| Wireless Protocol Standard | IEEE 802.15.4 |
| Frequency band | Sub 1 GHz |
| Sensor Type | Smart DC Power measurement |
| Typical transmission range | 10 to 30 meters indoors between any |
| | two devices in mesh network |
| Wireless network protocol | Frequency hopping self-configuring |
| | load-balancing mesh |
| Monitoring unit to gateway ratio | Up to 100 monitoring units per gateway |
| Housing Material | Polycarbonate (PC) |
| Weight (Approx.) | 100 gm |
| Dimensions (Approx.) | 84 mm × 63 mm × 31 mm |
| Operating Temperature | −10° C to +55° C |
| Ambient Humidity | ≤95% RH |
| Water & Dust Resistance | Indoor use |
| Input Power Supply | 48 V DC |
| No. of Input Power Supply | 1 |
| Rated Current Measurement | 150 A |
| Hall Sensor Type | Split Core |
| No. of interfaces to Hall Sensors | 1 |
| No. of Interfaces to Environment | 1 |
| Sensor | |
| Antenna | Fully enclosed, fixed configuration |
| Electrostatic Discharge | 8 KV |
| Mounting Option | 3M Tape |

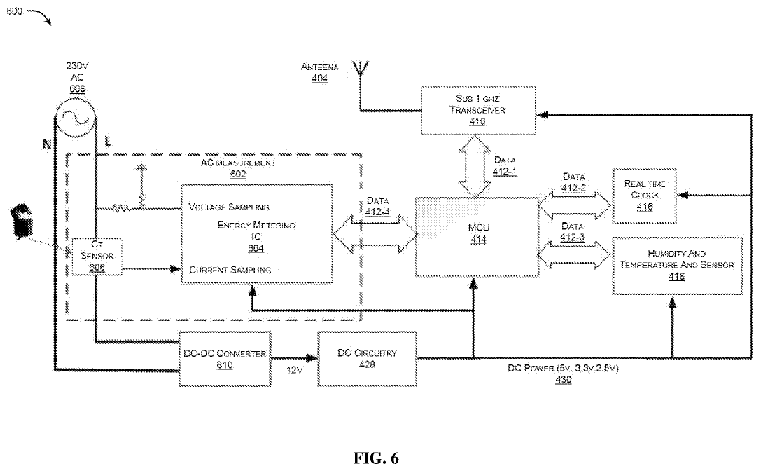

FIG. 6 illustrates an exemplary representation (600) of a functional block diagram of AC smart power sensor and its implementation, in accordance with an embodiment of the present disclosure. The proposed non-invasive AC Smart power sensor (600) may measure AC input supply current and voltage (608) and may keep accumulating the total energy consumed by the load in the device storage. All the energy consumption data will be appropriately time stamped using RTC (416) for data analytics purposes in the Cloud. The accumulated energy consumption data may be pushed periodically as per a network driven scheduling mechanism. In an embodiment, a plurality of sensors (also referred to as devices hereinafter) may communicate with an energy measurement gateway device in the network (106) for pushing an energy consumption data as per scheduled configuration. In an exemplary embodiment, the network may be a mesh topology network. The AC smart sensor may include an energy metering device (604) for measuring the current and voltage information which may be further processed by the processor (414) with DSP capability to calculate Active Power, Reactive Power, Apparent power and power factor and the like. The data communication RF interface between the energy measurement gateway device and the devices may be based on sub-GHz connectivity. In an exemplary embodiment, in addition to the above two sensors, there may a provision of a third sensor that may be an environment sensor on both the AC and DC Smart power sensors which may measure temperature and humidity at each rack level continuously and forward these data to the cloud.

In an exemplary embodiment, the AC smart senor (600) may include a split core current transformer (CT) (606) but not limited to it which may have higher turns ratio so as to convert a very high primary current into comparatively low secondary current and may be utilized herein as a current sampling device. The Energy Metering device (604) may be a single-phase energy metering IC but not limited to it which may have integrated ADC and DSP capabilities. The Energy Metering device (604) may perform a voltage sampling and current sampling activity. The Energy Metering device (604) may also perform the AC measurements for voltage, current, power factor, frequency, active power, reactive power, apparent power and the like. The Energy Metering device (604) further may interact with the MCU (414) on a serial interface but not limited to it. The Sub-1 GHz Transceiver may be utilized to transfer the second set of signals at RF frequency. The Sub-1 GHz Transceiver may interact with the MCU (414) and upon instructions by the MCU (414) may transfer the second set of signals to the antenna (404). The DC circuit (428) that may include the plurality of DC-DC convertors may be used to generate the required voltage supplies such as 5V, 3.3V and 2.5V for the board but not limited to the like. An AC-DC convertor (610) may be used to generate 12V output from 230V ac input but not limited to it. The temperature and humidity sensor (418) that may be a sensor chipset which may check temperature and humidity, and may update the MCU (414) of the measurements in a periodic manner which is controllable at the MCU (414).

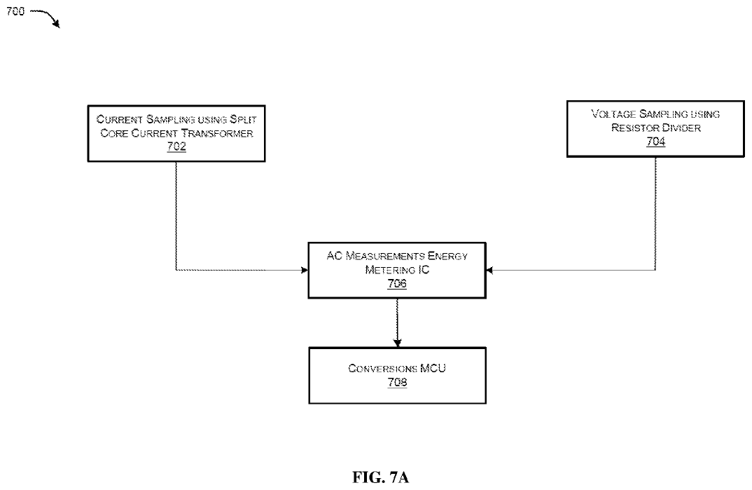

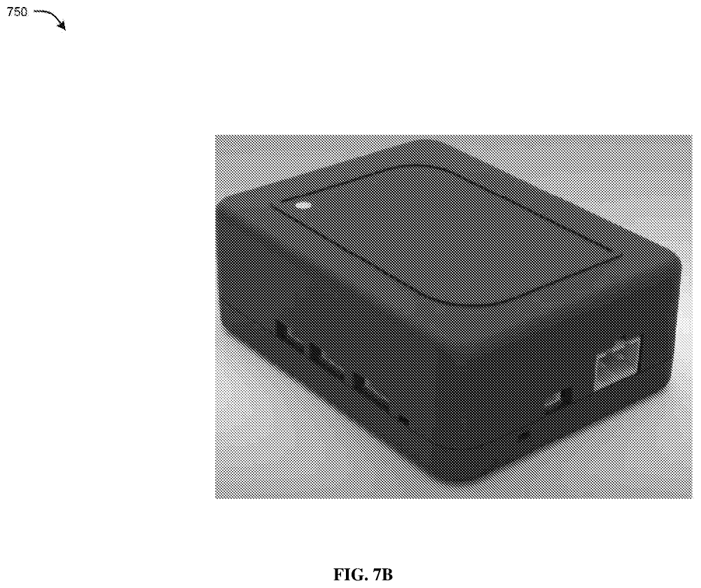

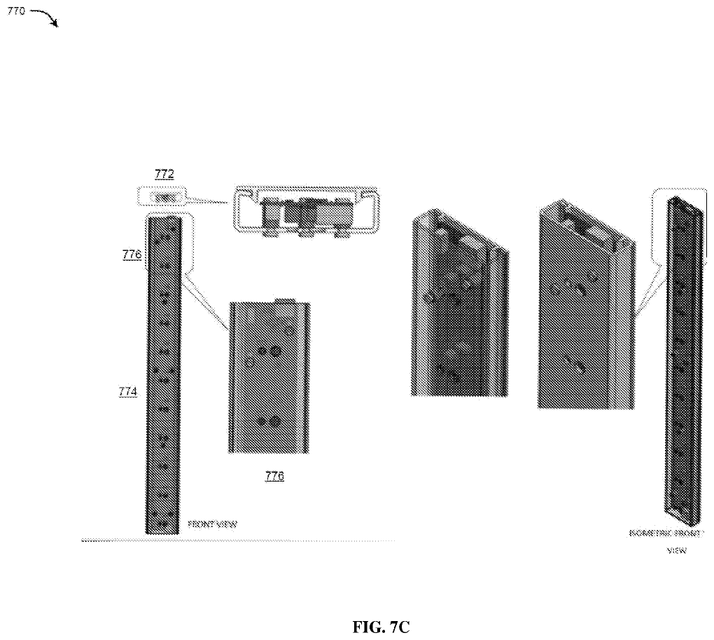

FIG. 7A illustrates an exemplary representation (700) of a flow diagram for AC Power Measurement method, in accordance with an embodiment of the present disclosure. As illustrated, the steps followed in the AC power measurement (700) may include at 702 an AC current sampling being done using the Split core current transformer and at 704 an AC voltage sampling being done using resistor divider network. In an exemplary embodiment, the AC Power measurement may include at 706 the step of performing sampling activities by the energy metering IC that may have integrated ADCs. The energy Metering IC may be calibrated as per mentioned guidelines in a datasheet of the energy Metering IC. In an embodiment, the measurement values may be stored in a plurality of registers operatively coupled the energy metering IC. In an exemplary embodiment, on serial interface the MCU may fetch data from the energy metering IC for AC parameters such as voltage, current, frequency, power factor, instantaneous power, active power, reactive power, apparent power and the like. The AC Power measurement may include at 706 the step of converting the measurement values read by the MCU into corresponding values for a parameter after considering the electronic circuit characteristic.

FIG. 7B illustrates an exemplary representation (750) of an AC Power sensor, in accordance with an embodiment of the present disclosure. In a way of example and not as a limitation, Table 2 highlights exemplary features of the DC power sensor.

TABLE 2

| Product Spec | Parameters |
|---|---|
| Network interface | Wireless |
| Frequency band | Sub 1 GHz |
| Wireless Protocol Standard | IEEE 802.15.4 |
| Sensor Type | Smart AC Power measurement |
| Typical transmission range | 10 to 30 meters indoors between any |
| | two devices in mesh network |
| Wireless network protocol | Frequency hopping self-configuring |
| | load-balancing mesh |
| Monitoring unit to gateway ratio | Up to 100 monitoring units per gateway |
| Housing Material | Polycarbonate (PC) |
| Weight (Approx.) | 100 gm |
| Dimensions (Approx.) | 84 mm × 63 mm × 31 mm |
| Operating Temperature | −10° C. to +55° C. |
| Ambient Humidity | <95% RH |
| Water & Dust Resistance | Indoor use |
| Input Power Supply | 230 V AC |
| No. of Input Power Supply | 1 |
| Rated Current Measurement | 30 A |
| CT Sensor Type | Split Core |
| No. of interfaces to Hall Sensors | 1 |
| No. of Interfaces to Environment | 1 |
| Sensor | |
| Antenna | Fully enclosed, fixed configuration |
| Electrostatic Discharge | 8 KV |
| Mounting Option | 3M Tape |

FIG. 7C illustrates a front view and an iso metric view representation of the DC Power sensor, the AC power sensor and other sensors in a rack of a data centre. As illustrated in FIG. 7C, the DC Power sensor, the AC power sensor and other sensors (772) are located on a sleeve (774) that is configured to hold a plurality of such sensors (772). The sleeve (774) is placed on a rack of the data centre. A portion (776) of the sleeve (774) having the DC Power sensor, the AC power sensor and other sensors is shown in an enlarged view (776). It can be clearly seen from the FIG. 7, that the plurality of DC Power sensor, AC power sensor and other sensors are placed in a predefined location at a predefined distance from each other.

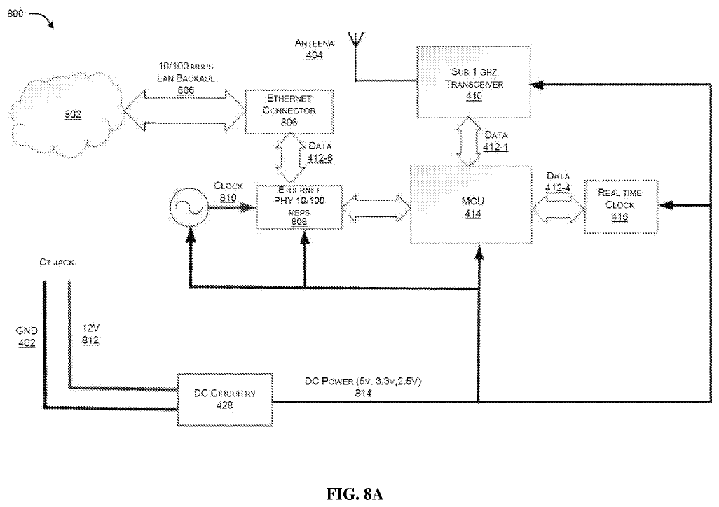

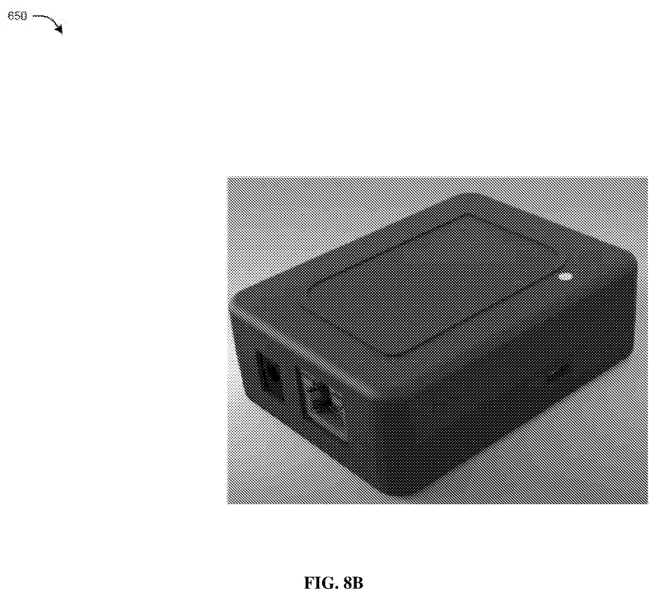

FIG. 8A illustrates an exemplary representation (800) of a functional block diagram of wireless network gateway and its implementation, in accordance with an embodiment of the present disclosure. In an aspect the system (110) may include a wireless gateway device (800) that can collect data periodically from at least 50-100s of sensors (also referred to as the AC/DC Energy measurement devices) deployed in the data centres using sub-GHz RF interface connected in the mesh network. The wireless gateway device (800) may send the collected data to cloud (802) on but not limited to a 10/100 Mbps LAN Ethernet (808) interface for data analytics and post processing for audit purposes. The wireless gateway device (800) may be powered using an AC/DC power adaptor. The wireless gateway device (800) may comprise of at least a 32 bit high end MCU but not limited to it to provide the collected data from the plurality of sensors to 10/100 Mbps LAN interface (804) through a 10/100 Ethernet PHY transceiver followed by magnetic and LAN connector (806). The wireless gateway device (800) may also comprise of the DC circuitry (428) to provide respective voltages to all other devices and the sub 1 GHz wireless transceiver (410) to collect the AC/DC sensor, the Rack space sensor Temperature and Humidity sensor data over the air. The antenna (404) may listen to all the data of the plurality of sensors. The Ethernet PHY (808) may be a 10/100 Mbps Ethernet transceiver which is IEEE 802.3u compliant. The Ethernet PHY (808) may interact with the MCU (414) and a cloud server. The data received from the plurality of sensors may be shared to the cloud (802) by the MCU (414) with the help of Ethernet PHY (808). The DC circuit (428) comprising a plurality of DC-DC convertors may be used to generate the required voltage supplies 3.3V for the board.

FIG. 8B illustrates a representation of the wireless gateway device. In a way of example and not as a limitation, the Table 3 highlights exemplary features of the wireless gateway device.

TABLE 3

| | |
|---|---|
| Network interface | Ethernet with SNMP |
| Frequency band | Sub 1 GHz |
| Wireless Protocol Standard | IEEE 802.15.4 |
| Typical wireless transmission | 10 to 30 meters indoors between any two |
| range | devices in mesh network |
| Monitoring units to gateway | Up to 100 Sensor (AC/DC) units per |
| ratio | gateway |
| Housing Material | Polycarbonate (PC) |
| Weight (Approx.) | 100 gm |
| Dimensions (Approx.) | 82 mm × 62 mm × 28 mm |
| Operating Temperature | −10° C. to 55° C. |
| Ambient Humidity | ≤95% RH |
| Water & Dust Resistance | Indoor use |
| External Power Supply | 100 to 240 V AC input; 50/60 Hz |
| | (12 V DC) output |
| Firmware updates | Wireless |
| Antenna | Fully enclosed, fixed configuration |
| Mounting Options | 3M Tape |
| Power Consumption | 3 W |
| Electrostatic Discharge | 8 KV |

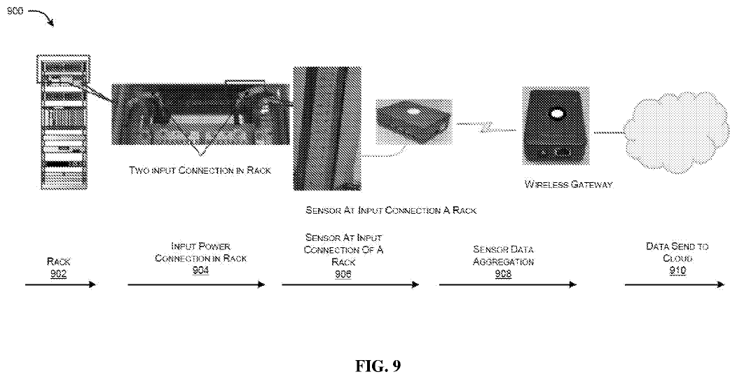

FIG. 9 illustrates an exemplary representation (900) of a flow diagram of data flow from the rack Sensor to cloud, in accordance with an embodiment of the present disclosure. As illustrated, in an aspect, the wireless network gateway device is a wireless device that may interact with at least 50-100 energy sensor data. The energy sensor data may be shared with the cloud on LAN interface for data analytics. In an exemplary embodiment, a Sub-1 GHz module may receive data from each energy sensor in periodic manner, arrange the received data in a pre-defined format and forward data to the cloud on LAN interface. The functional data flow (900) shows how data is transmitted from a rack sensor (902, 904, 906, 908 and 910) to the cloud while using DC/AC smart power sensors and the wireless gateway device.

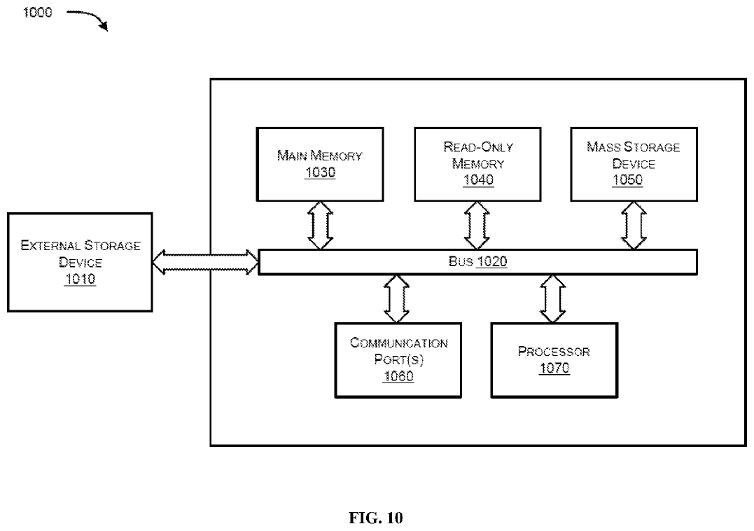

FIG. 10 illustrates an exemplary computer system in which or with which embodiments of the present invention can be utilized in accordance with embodiments of the present disclosure. As shown in FIG. 10, computer system (1000) can include an external storage device (1010), a bus (1020), a main memory (1030), a read only memory (1040), a mass storage device (1070), communication port (1060), and a processor (1070). A person skilled in the art will appreciate that the computer system may include more than one processor and communication ports. Examples of processor (1070) include, but are not limited to, an Intel® Itanium® or Itanium 2 processor(s), or AMD® Opteron® or Athlon MP® processor(s), Motorola® lines of processors, FortiSOC™ system on chip processors or other future processors. Processor (1070) may include various modules associated with embodiments of the present invention. Communication port (1060 can be any of an RS-232 port for use with a modem-based dialup connection, a 10/100 Ethernet port, a Gigabit or 10 Gigabit port using copper or fiber, a serial port, a parallel port, or other existing or future ports. Communication port (1060 may be chosen depending on a network, such a Local Area Network (LAN), Wide Area Network (WAN), or any network to which computer system connects. Memory 1030 can be Random Access Memory (RAM), or any other dynamic storage device commonly known in the art. Read-only memory (1040) can be any static storage device(s) e.g., but not limited to, a Programmable Read Only Memory (PROM) chips for storing static information e.g., start-up or BIOS instructions for processor (1070). Mass storage (1050) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 7102 family) or Hitachi (e.g., the Hitachi Deskstar 7K1000), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

Bus (1020) communicatively couple processor(s) (1070) with the other memory, storage and communication blocks. Bus (1020) can be, e.g., a Peripheral Component Interconnect (PCI)/PCI Extended (PCI-X) bus, Small Computer System Interface (SCSI), USB or the like, for connecting expansion cards, drives and other subsystems as well as other buses, such a front side bus (FSB), which connects processor (1070) to software system.

Optionally, operator and administrative interfaces, e.g. a display, keyboard, joystick and a cursor control device, may also be coupled to bus (1020) to support direct operator interaction with a computer system. Other operator and administrative interfaces can be provided through network connections connected through communication port (1060). The external storage device (1010) can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

Thus, the present disclosure provides a unique and inventive solution for measuring power in a plurality of racks in a data centre with the help of at least two types of power sensors—DC Smart Power Sensor (Non-invasive DC Smart PDU) and AC Smart Power Sensor (Non-invasive AC Smart PDU) which continuously measure −48V DC and 230V AC power consumption respectively input supply current and voltage and keeps accumulating the total energy consumed by the load in the device storage. All the energy consumption data is appropriately time stamped using real time clock (RTC) for data analytics purposes in the Cloud. The accumulated energy consumption data may be pushed periodically as per network driven scheduling mechanism.

Typically, the power sensors have two hardware devices—1) Current sensor and 2) Wireless Adaptor. The current sensor which measures AC current is called current transformer (CT) and for measuring DC current is called Hall Sensor. The Wireless adaptor takes current measurement from current sensor, reads the line voltage from the input supply and calculate the energy consumption (in watt) from current and voltage value. These energy parameters (i.e., current, voltage and power consumption) may be then transmitted to the Cloud over wireless interface.

In addition to energy parameters, in an embodiment, the wireless adaptor may also provide wire connectivity with an environment sensor. The environment sensor may measure temperature and humidity in each rack area and may send to the wireless adaptor. The wireless adaptor may forward the environment parameters to the cloud via the wireless network gateway device. The wireless network gateway device may collect data periodically from a plurality of AC/DC Smart power sensors deployed in the entity using sub-GHz RF interface connected in a mess network. The wireless network gateway device may send the so collected data to the cloud on a 10/100 Mbps Ethernet interface for data analytics and post processing for audit purposes. The device will be powered using an AC/DC Power adaptor. The Data collection RF interface between gateway and measurement devices is based on sub-GHz for better coverage and connectivity.

The present disclosure provides a zero-rack space because the plurality of sensors is very small and, hence no rack space is required to install these devices. Moreover, the small size sensors are very easy to handle and can be easily integrated with the antenna without disturbing the property of antenna. A cost-effective solution as compared to the available solutions is provided wherein the cost is approximately 95% less than its peers. Furthermore, the plurality of sensors may be connected to the same wireless gateway and thus one gateway can support connectivity up to at least 100 sensors but not limited to it. The present invention also provides a zero service down time as no service downtime is required to install the sensors.

While considerable emphasis has been placed herein on the preferred embodiments, it will be appreciated that many embodiments can be made and that many changes can be made in the preferred embodiments without departing from the principles of the invention. These and other changes in the preferred embodiments of the invention will be apparent to those skilled in the art from the disclosure herein, whereby it is to be distinctly understood that the foregoing descriptive matter to be implemented merely as illustrative of the invention and not as limitation.

### Advantages of the Present Disclosure

The present disclosure provides a system and a method that uses zero rack space as devices are very small, hence no rack space is required to install these devices.

The present disclosure provides a system and a method facilitates use of small size devices which are very easy to handle and easy to integrate with the antenna without disturbing the property of antenna.

The present disclosure provides a cost-effective solution as compared to the available solutions where the cost is approximately 95% less than its peers.

The present disclosure provides a system and a method that has zero service down time i.e., no service downtime required to install the sensors.

We claim:

1. A system (110) for facilitating rack wise power measurement of a data centre (108) of an entity (114), said system comprises:
a wireless sensor monitoring device, said wireless sensor monitoring device (116) comprising a plurality of sensors, said plurality of sensors operatively coupled to a plurality of racks of the data centre (108), wherein said plurality of sensors is configured to sense a current flowing through each rack of the data centre (108) and wherein the plurality of sensors outputs a voltage corresponding to the current;
a processor (202), operatively coupled to the wireless sensor monitoring device (116) through a network (106), said processor (202) coupled with a memory (204), wherein said memory (204) stores instructions which when executed by the processor (202) causes the processor (202) to:
receive a first set of signals from the plurality of sensors, the first set of signals pertaining to a DC current and DC voltage corresponding to each of the plurality of racks;
receive a second set of signals from the plurality of sensors, the second set of signals pertaining to an AC current and AC voltage corresponding to each of the plurality of racks;
extract a first set of attributes from the first set of signals, the first set of attributes pertaining to one or more sampled values of the DC current and DC voltage;
extract a second set of attributes from the second set of signals, the second set of attributes pertaining to one or more sampled values of the AC current and AC voltage; and,
based on the extracted first and second set of attributes, calculate a power value for each first and second set of attributes extracted within a specified interval of time.

2. The system as claimed in claim 1, wherein the processor (202) further determines a cumulative energy from the power value for each first and second set of attributes extracted over the specified interval of time.

3. The system as claimed in claim 1, wherein the processor (202) further determines a total power consumed by the plurality of racks in the data centre.

4. The system as claimed in claim 4, wherein the wireless sensor monitoring device further comprises a microcontroller unit (MCU) (414) and an antenna (404) operatively coupled to a transceiver (410) and one more modules coupled to a DC circuitry (428).

5. The system as claimed in claim 1, wherein the plurality of sensors is any or a combination of one or more DC Smart Power Sensors and one or more AC Smart Power Sensors.

6. The system as claimed in claim 1, wherein a centralised server (112) operatively coupled to the processor (202) stores a plurality of DC current and voltages, a plurality of AC currents and voltages, a plurality of sampled AC and DC current and voltage values, a plurality of power values corresponding to the sampled AC and DC current and voltage values.

7. The system as claimed in claim 1, wherein the plurality of sensors is of a predefined size placed at predetermined locations in each said rack.

8. The system as claimed in claim 1, wherein a user device (104) is communicably coupled to the centralized server (112) through the network (106), wherein the user device (104) enables a user (102) to store, access and monitor the centralized server (112) remotely through the network (106).

9. A wireless gateway device (120) for collecting rack wise power measurement data of a data centre (108) of an entity (114), said device comprises:
an antenna unit, said antenna unit collects a power measurement of the plurality of racks determined by the system (110);
a local area network (LAN), said LAN operatively coupled to a centralized server (112) through a network (106);
a processor (222), said processor coupled with a memory (224), wherein said memory stores instructions which when executed by the processor causes the processor (222) to:
receive the power measurement of the plurality of racks determined by the system (110);
transmit the received power measurement to the centralized server (112) though the LAN.

10. The device as claimed in claim 9, wherein the wireless gateway device (120) is of a predetermined size that do not require any rack space.

11. The device as claimed in claim 9, wherein the centralised server (112) stores a plurality of DC current and voltages, a plurality of AC currents and voltages, a plurality of sampled AC and DC current and voltage values, a plurality of power values corresponding to the sampled AC and DC current and voltage values associated with the data centre.

12. The device as claimed in claim 11, wherein a user device (104) is communicably coupled to the centralized server (112) through the network (106), wherein the user device (104) enables a user (102) to store, access and monitor the centralized server (112) remotely through the network (106).

13. The device as claimed in claim 9, wherein the device is further configured to manage a plurality of systems (110).

14. A method for facilitating rack space measurement of a data centre (108) of an entity (114), said method comprises:
receiving, by a processor, a first set of signals from the plurality of sensors, the first set of signals pertaining to a DC current and voltage flowing through each rack, wherein the plurality of sensors pertains to a wireless sensor monitoring device,
wherein said plurality of sensors are operatively coupled to a plurality of racks of the data centre (108), wherein said plurality of sensors is configured to sense a current flowing through each rack of the data centre (108) and wherein the plurality of sensors outputs a voltage corresponding to the current,
and wherein the processor (202) is operatively coupled to the wireless sensor monitoring device (116) through a network (106), said processor (202) coupled with a memory (204), wherein said memory (204) stores instructions are executed by the processor (202);
receiving, by the processor, a second set of signals from the plurality of sensors, the second set of signals pertaining to an AC current and voltage flowing through each said rack;
extracting, by the processor, a first set of attributes from the first set of signals, the first set of attributes pertaining to one or more sampled values of the DC current and voltage;
extracting, by the processor, a second set of attributes from the second set of signals, the second set of attributes pertaining to one or more sampled values of the AC current and voltage; and,
based on the extracted first and second set of attributes, calculating, by the processor, a power value for each first and second set of attributes extracted within a specified interval of time.

15. The method as claimed in claim 14, wherein the method further comprises:
determining by the processor (202), a cumulative energy from the power value for each first and second set of attributes extracted over the specified interval of time.

16. The method as claimed in claim 14, wherein the method further comprises:
determining by the processor (202), a total power consumed by the plurality of racks in the data centre.

17. The method as claimed in claim 14, wherein the wireless sensor monitoring device further comprises a microcontroller unit (MCU) (414) and an antenna (404) operatively coupled to a transceiver (410) and one more modules coupled to a DC circuitry (428).

18. The method as claimed in claim 14, wherein the plurality of sensors is any or a combination of one or more DC Smart Power Sensors and one or more AC Smart Power Sensors.

19. The method as claimed in claim 13, wherein a centralised server (112) operatively coupled to the processor (202) stores a plurality of DC current and voltages, a plurality of AC currents and voltages, a plurality of sampled AC and DC current and voltage values, a plurality of power values corresponding to the sampled AC and DC current and voltage values.

20. The method as claimed in claim 18, wherein the plurality of sensors is of a predefined size placed at predetermined locations in each said rack.
